(19) United States
(12) Patent Application Publication
(10) Pub. No.: US 2012/0234373 A1
(43) Pub. Date: Sep. 20, 2012

(54) Reflection Solar

(76) Inventor: Steven M. Colby, Los Altos, CA (US)

(21) Appl. No.: 13/420,417

(22) Filed: Mar. 14, 2012

Related U.S. Application Data
(60) Provisional application No. 61/453,679, filed on Mar. 17, 2011.

(51) Int. Cl. H01L 31/052; H01L 31/0224; H01L 31/18; H01L 31/0232

(52) U.S. Cl. 136/246; 136/259; 136/256; 438/69; 257/E31.127

(57) ABSTRACT

A photovoltaic device includes a reflection region configured to direct light multiple times at a photoelectric material. Charge separation occurs in the photoelectric material when light is reflected at a thin reflector and part of the light's electric field penetrates the reflector into the photoelectric material. The charge separation is typically used to provide an electric current to a load.

### CROSS-REFERENCE TO RELATED APPLICATIONS

This application claims priority and benefit of U.S. Provisional Patent Application Ser. No. 61/453,679 filed Mar. 17, 2011. The disclosure of this provisional patent application is hereby incorporated herein by reference.

### BACKGROUND

1. Field of the invention

The invention is in the field of photovoltaic cells and associated technology.

2. Related Art

Historically, crystalline silicon (c-Si) has been used as the light-absorbing semiconductor in most photovoltaic (solar) cells, even though it is a relatively poor absorber of light and requires a considerable thickness (several hundred microns) of material. Nevertheless, it has proved convenient because it yields stable solar cells with good efficiencies (15-17%, half to two-thirds of the theoretical maximum) and uses process technology developed from the huge knowledge base of the microelectronics industry.

Other materials used are amorphous silicon (a-Si), microcrystalline silicon or the polycrystalline materials: cadmium telluride (CdTe), copper indium (gallium), and diselenide (CIS or CIGS). Also combinations of organics, Group XI, XIII, and/or XVI elements and mixtures of materials have been studied.

One area of advance in photovoltaic technology has been the area of thin film solar cells. Thin film solar cells can be more efficient because, for example, electron collection efficiency is greater from a thin photoelectric. Amorphous silicon is the most developed of the complex thin film technologies. In its simplest form, the cell structure including a photoelectric layer having a single sequence of p-i-n layers. Such cells suffer from significant degradation in their power output (in the range of 15-35%) when exposed to the sun. Thinner layers can be used to increase the electric field strength across the material and to provide better stability. However, the use of thinner layers reduces light absorption, and hence cell efficiency. If a layer is too thing a reduced number of charge separations are produce per photon. There has been, thus, a tradeoff between electron collection efficiency and the production of charge separations. This has been thought to fundamentally limit the overall efficiency of thin film technologies.

The photovoltaic layer in solar cells typically includes a n-i-p or p-i-n junction. The “p” material is normally disposed on the side from which light is received because of the differences in hole v. electron migration efficiencies. The industry has developed tandem and even triple layer devices that contain p-i-n cells, stacked one on top of the other. In the cell, at the base of the structure, the a-Si is sometimes alloyed with germanium to reduce its band gap and to further improve light absorption. This added complexity has a downside though; the processes are more complicated, and process yields are likely to be lower.

Plasmonic solar cells (PSC) are a class of photovoltaic devices that convert light into electricity by using plasmons. PSCs are a type of thin-film solar cell that are typically 1-2 μm thick. They can use substrates which are cheaper than silicon, such as glass, plastic or steel. The biggest problem for thin film solar cells is that they don't absorb as much light as the thicker solar cells. Methods for trapping light on the surface, or in the solar cell has been thought to be important in order to make thin film solar cells viable. One method which has been explored over the past few years is to scatter light using metal nanoparticles excited at their surface plasmon resonance. This allows light to be absorbed more directly without the relatively thick additional layer required in other types of thin-film solar cells.

### SUMMARY

A photovoltaic system uses a part of an electromagnetic wave that penetrates a reflector to produce charge separation in a photovoltaic material. This charge separation is used to generate an electric current. While the efficiency of producing charge separation through a reflector may be lower than without the reflector, one or more reflectors are typically disposed such that most electromagnetic waves are reflected multiple times. The multiple reflections increase the number of opportunities that a photon has to create a charge separation and, thus, to a significant extent make up for the difference in production efficiency. The reflector is disposed so as to reflect light away from the photovoltaic material. Light is trapped in a reflection region external to the photovoltaic material.

Charge separation occurs in a very narrow region of the photovoltaic material. For example, in various embodiments the majority of charge separation occurs within one wavelength or within ½ wavelength of the reflective surface. This produces advantages normally associated with thin film photovoltaic devices while avoiding some of the disadvantages. The depth of the region in which charge separation occurs is optionally adjusted by varying the thickness of the reflective material, the make-up of the reflective material, the make-up of the photovoltaic material, and/or the angle of incidence of the light.

Various embodiments of the invention comprise a photovoltaic system including a reflection region configured for light to be repeatedly reflected from a first reflector, the first reflector being conductive and having a thickness configured for an electric field of the reflected light to penetrate through the first reflector; a first junction region comprising a photovoltaic material configured to absorb a photon from the penetrating electric field so as to produce a separation of charges; and a first counter electrode configured to receive one of the separated charges, resulting in a voltage differential between the first reflector and the first counter electrode.

Various embodiments of the invention comprise a photovoltaic system including a first electrode; a junction region in electrical contact with the first electrode; and a second electrode in electrical contact with the junction region, configured to reflect at least 20% of incident light, and disposed such that energy of the photon passes through the second electrode in order to reach the junction region, wherein the photon adsorption material is configured to produce a charge separation from the photon energy passed through the second electrode.

Various embodiments of the invention comprise an electric power generation system including a plurality of photoelectric devices each comprising a first electrode including a first reflector, a second electrode configured to reflect at least 20% of incident light, and a junction region disposed between the first electrode and the second electrode and configured to produce a charge separation from photon energy received through the second electrode; and a load configured to receive a current resulting from the charge separation produced at each of the plurality of the electric devices.

Various embodiments of the invention comprise a method of converting light to an electric current, the method including receiving the light; directing the received light into a reflection region comprising reflective surfaces; reflecting the light from the reflective surfaces; using an electric field to produce a charge separation within a junction region, the electric field resulting from the received light and penetrating through one of the reflective surfaces during a photon reflection; and using the charge separation to produce the electric current.

Various embodiments of the invention comprise a method of producing a photovoltaic, the method including generating a thin reflector configured for an electric field to penetrate upon reflection of a photon, the thin reflector being configured to conduct a charge and to reflect at least 20% of incident photons; generating a junction region in contact with the thin reflector and configured to produce a charge separation from the penetrating electric field; generating a counter electrode in contact with the junction region, the junction region being disposed between the counter electrode and the thin reflector such that an electric field must penetrate the thin reflector to produce the charge separation; and generating a reflection region configured such that a photo reflects from the thin reflector multiple times.

### BRIEF DESCRIPTION OF THE DRAWINGS

FIGS. 1A and 1B illustrate two reflection systems, according to various embodiments of the invention.

FIGS. 2A and 2B illustrate reflection systems including a light guide, according to various embodiments of the invention.

FIG. 3 illustrates various cross-sections of a reflection system, according to various embodiments of the invention.

FIG. 4 illustrates a reflection system including regions that require different amounts of photon energy to generate a charge separation, according to various embodiments of the invention.

FIG. 5 illustrates a reflection system including particles disposed adjacent to a reflector, according to various embodiments of the invention.

FIG. 6 illustrates ways in which reflection systems can be bundled, according to various embodiments of the invention.

FIG. 7 illustrates an array of reflection systems coupled to a light guide, according to various embodiments of the invention.

FIG. 8 illustrates methods of generating an electronic current, according to various embodiments of the invention.

FIG. 9 illustrates methods of making a reflection system, according to various embodiments of the invention.

### DETAILED DESCRIPTION

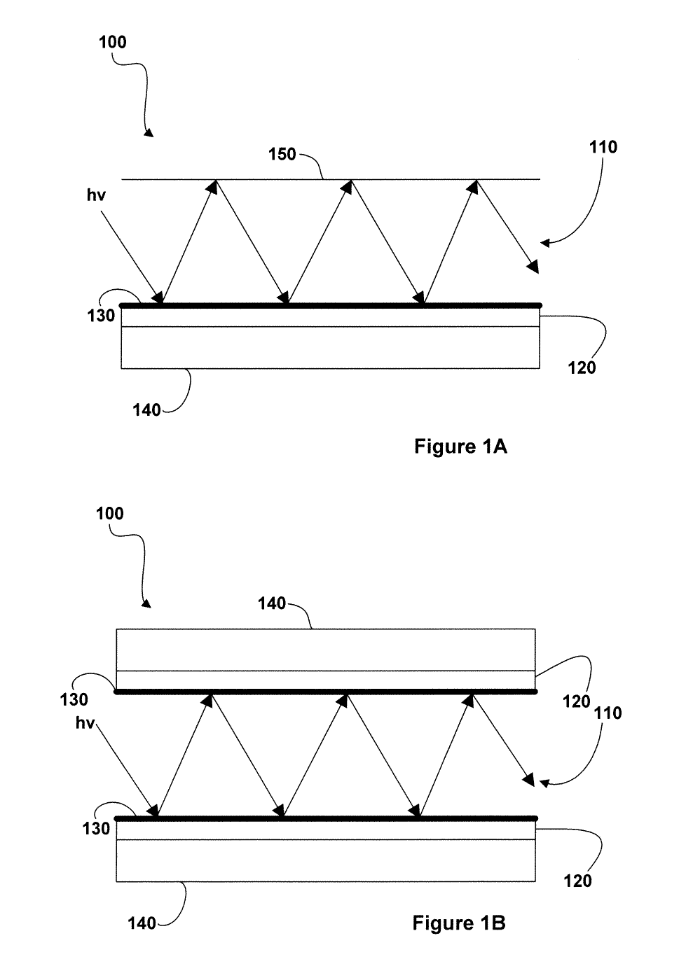

As illustrated in FIGS. 1A and 1B, a Reflection System 100 comprises a Reflection Region 110 in which light (hv) is reflected repeatedly between reflective surfaces. At least one, two or more sides of the Reflection Region 110 include a Thin Reflector 130. Thin Reflector 130 is configured to reflect light and to be thin enough such that a portion of the light's electric field is felt within a photovoltaic Junction Region 120 on a side of Thin Reflector 130 opposite the side on which the reflection occurs. In various embodiments, Thin Reflector 130 is configured to reflect greater than 20, 50, 75, 90, 98, 99, or 99.9% of the incident light. The presence of an electric field on the side of a thin reflector opposite that on which the light reflects is a known optical effect. Thin Reflector 130 typically includes a conductive, e.g., metal, surface disposed on one side of the Junction Region 120. For example, Thin Reflector 130 may include a thin layer of aluminum, copper, gold, silver, nickel, carbon, silicon, and/or the like. The conductive nature of Thin Reflector 130 allows it to accept or donate electrons. Thin Reflector 130, thus, is configured to operate as an electrode. Junction Region 120 is typically in electrical and/or mechanical contact with Thin Reflector 130 and is optionally present wherever Thin Reflector 130 is disposed. Junction Region 120 is also in electrical contact with a Counter Electrode 140. Junction Region 120 includes or is part of a photovoltaic material (e.g., an n-i-p or p-i-n junction). The “p” layer of this junction is optionally disposed on the side of Junction Region 120 adjacent to Thin Reflector 130. Thus, in this case, the “p” layer is on the side from which the electric field is received. In some embodiments the “p” or “n” layer is part of Thin Reflector 130.

In some embodiments, Thin Reflector 130 includes a photonic crystal of the bulk material that makes up Reflection Region 110. Thin Reflector 130 optionally includes graphite sheets or carbon nanostructures. The thickness of Thin Reflector 130 is typically selected to achieve the desired reflectivity while still allowing the penetrating electric field to reach Junction Region 120. In various embodiments, Thin Reflector 130 is a few atomic layers thick, less than 10, 50, 100, or 250 nanometers thick, or greater than 250 nanometers thick.

In combination, Junction Region 120, Thin Reflector 130 and Counter Electrode 140 form a photovoltaic cell. The photovoltaic cell is configured such that the electric field of a photon causes separation of charge. The separated charges move to Thin Reflector 130 and Counter Electrode 140, resulting in a voltage difference that can be used to supply an electrical current. In some embodiments, the photovoltaic cell is configured such that electrons are received by Thin Reflector 130 and electrons are received from Counter Electrode 140.

In some embodiments, the depth within Junction Region 120 in which charge separation can occur is limited by the penetration depth of the electric field that passed through Thin Reflector 130 into Junction Region 120. This depth can be less than two, one, ¼, ½, or ¼ of the wavelength of the light. Alternatively, this depth can be less than 1500, 1000, 750, 500, 250 or 100 nanometers. Junction Region 120 is optionally thicker than these depths. As such, charge separation may occur in only that part of Junction Region 120 closest to Thin Reflector 130. In some embodiments, the layers of the n-i-p or p-i-n junction that are part of Junction Region 120 are configured such that the “i” layer is disposed within the penetrating electric field, but an “n” or “p” layer is not.

The operation of Reflection System 100 allows light (photons) to reflect many times within Reflection Region 110. At each reflection there is a chance that the light will cause charge separation in the photovoltaic junction and, thus, be adsorbed. Because the light reflects from Thin Reflector 130 numerous times, each reflection provides another chance for photon adsorption resulting in charge separation. A photon may be directed at Junction Region 120 two or more times and, thus, have multiple chances to cause a charge separation. This increases the probability per reflecting photon that a charge separation will occur and can result in a more efficient photon to electricity conversion, relative to prior art. In various embodiments, a photon is reflected at Thin Reflector 130 more than 10, 50, 100, 1000, 10×10⁴, 10×10⁵ or 10×10⁶ times.

Reflection Region 110 optionally comprises an open space including an air gap or vacuum. Alternatively, Reflection Region 110 may comprise a transparent material. For example, Reflection Region 110 may comprise a glass, polycrystalline or crystalline material, a fiber optic, a transparent plastic, a liquid, and/or the like. Reflection Region 110 can be bounded by two approximately parallel plates, the walls of an open orifice, or other structures. In some embodiments, Thin Reflector 130 comprises a variation in the composition or density of a material that makes up Reflection Region 110. For example, techniques are known for migrating conductive ions to the surface of a bulk material such as glass and, thereby, giving the material a conductive surface. In some embodiments, Thin Reflector 130 is merely represented by a significant change in the index of refraction between Reflection Region 110 and Junction Region 120.

Instances of Thin Reflector 130, Junction Region 120 and Counter Electrode 140 are optionally disposed on more than one side of Reflection Region 110. For example, FIG. 1A illustrates embodiments having Thin Reflector 130 on one side and a Total Reflector 150 on another side. In contrast, FIG. 1B illustrates embodiments having Thin Reflector 130 on opposing sides such that light is reflected between Thin Reflectors 130. Reflection Region 110 may have more than two sides or may be circular or oval. For example, embodiments including a fiber optic as the Reflection Region 110 have a circular cross-section. The Thin Reflectors 130 and Counter Electrodes 140 illustrated in FIG. 1B may be cross sections of the same components, e.g., coatings that surround a fiber optic or other structure. As described further elsewhere herein, clusters of Reflection Region 110 are optionally bundled or stacked together. As such, embodiments of the invention optionally includes a bundle of fiber optics, a stack of approximately parallel plates, an array of orifices, and/or the like. Counter Electrodes 140 are optionally disposed in contact with a heat sink (not shown).

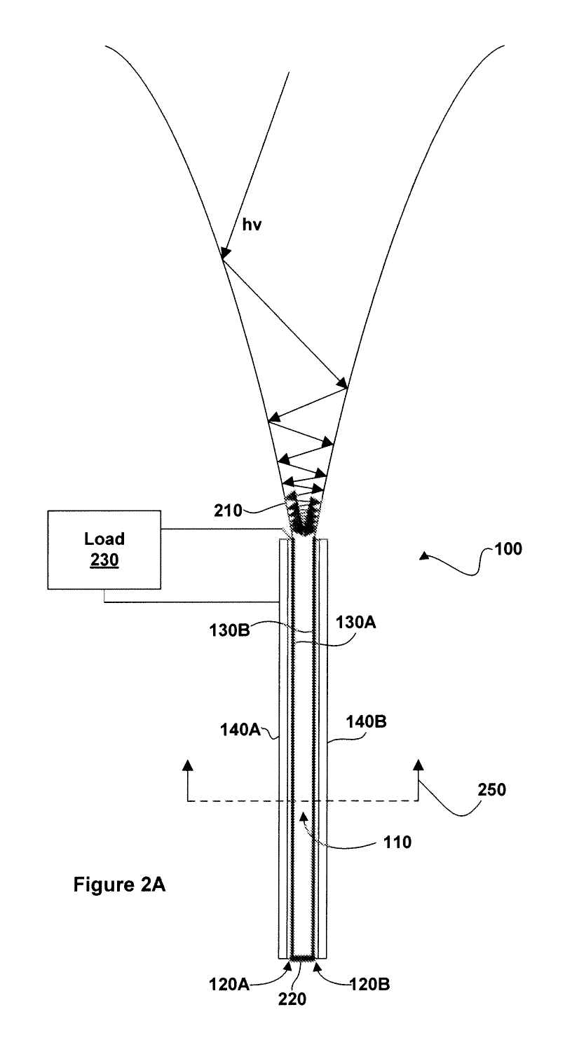

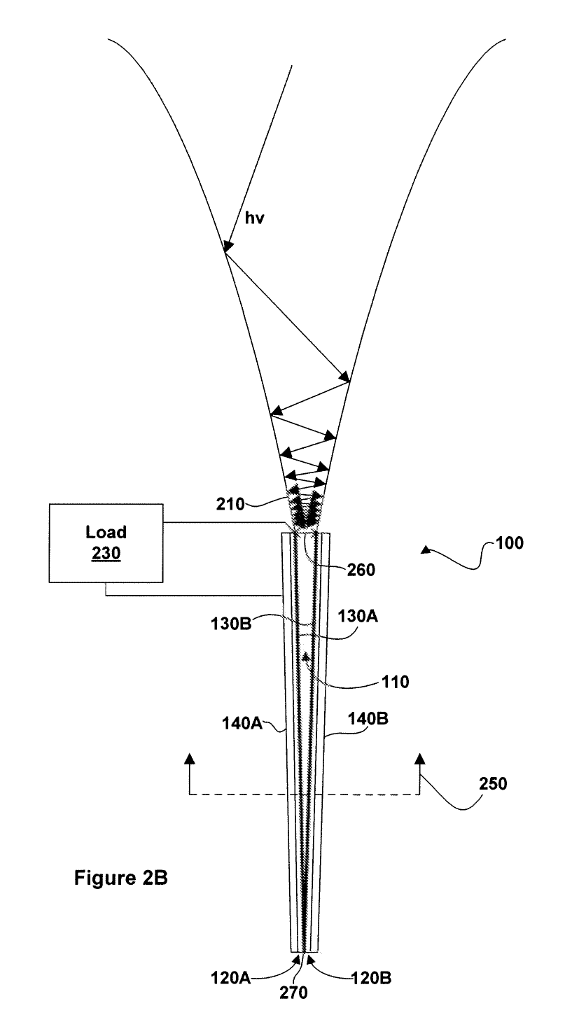

FIGS. 2A and 2B illustrate embodiments of Reflection System 100 including a Light Guide 210. Light Guide 210 is configured to receive light, and to direct the received light into Reflection Region 110. Light Guide 210 may include mirrors, fibers, lenses, light pipes, funnels, or any other device configured to direct light. For example, Light Guide 210 may include a plurality of mirrors configured to direct light to a light funnel. Light Guide 210 may be curved. Light Guide 210 is optionally configured to concentrate as well as direct the incoming light. As such, the intensity (Watt/m²) of light entering Reflection System 100 may be greater than “one sun.” FIG. 2 illustrates light being reflected within a light funnel. This reflection continues within Reflection Region 110, although these continued reflections are not shown in FIGS. 2A and 2B for clarity. In some embodiments, several instances of the Reflection System 100 illustrated in FIGS. 2A and 2B are disposed side-by-side so as to receive light over an extended area. A surface area of Junction Region 120 is optionally greater than an Area 260 over which light is received by Light Guide 210.

The embodiments of Reflection System 100 illustrated in FIG. 2A optionally further include a Terminal Reflector 220. Terminal Reflector 220 is configured to reflect any light that reaches the end of Reflection Region 110. As such, light reflected by Terminal Reflector 220 passes through Reflection Region 110 again. Terminal Reflector 220 may include a mirror or a prism. In some embodiments, terminal reflector includes a third instance of Thin Reflector 130, Reflection Region 110 and Counter Electrode 140. Reflection Region 110 is optionally tapered to terminate in a Point 270 as illustrated in FIG. 2B.

The embodiments of Reflection System 100 illustrated in FIGS. 2A and 2B typically further include a Load 230. Load 230 is configured to receive a current generated as a result of the charge separation that occurs within Junction Region 120. Load 230 can include a battery, a motor, a DC to AC converter, a DC to DC converter, an electrochemical cell, an electrical storage device, an electrochemical cell, and/or the like.

The embodiments of Reflection System 100 illustrated in FIGS. 2A and 2B optionally also include two or more instances each of Junction Region 120, Thin Reflector 130 and Counter Electrode 140. These instances are individually labeled 120A, 120B, 130A, 130B, 140A, and 140B, respectively. These two instances are disposed on opposing sides of Reflection Region. A photon within Reflection Region 110 has multiple opportunities to be converted to a charge separation as it is reflected between different Thin Reflector 130 or different parts of the same Thin Reflector 130.

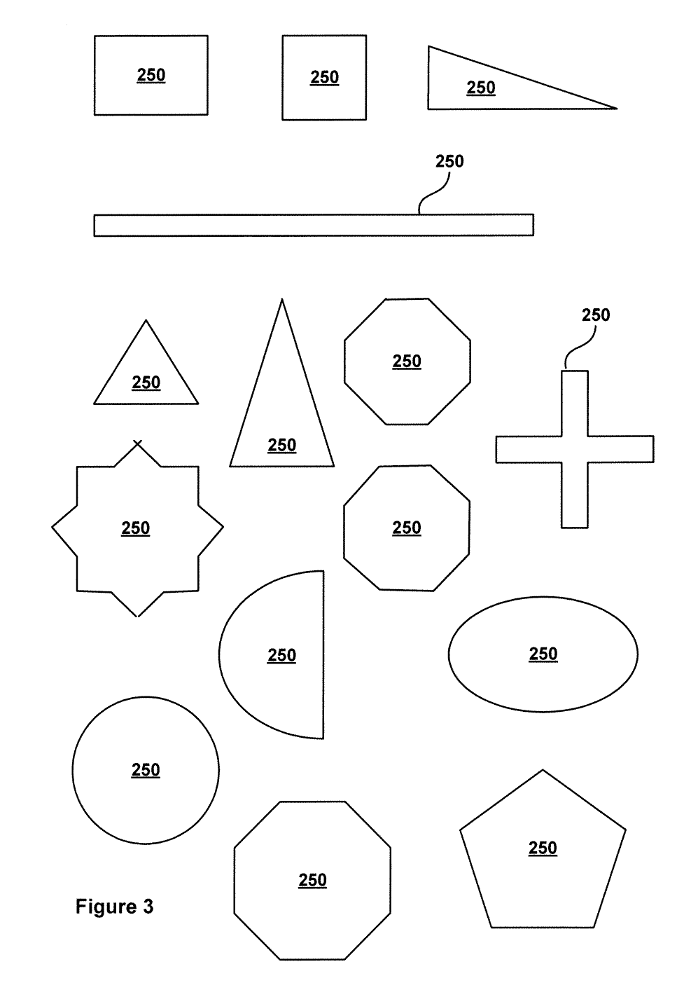

FIG. 3 illustrates alternative Cross-sections 250 of Reflection System 100, including a polygon, such as a triangle, square, hexagon, and/or the like. Alternatively, cross-sections 250 may include a curved surface, an oval, a circle, a parabola, cross, and/or the like. When Cross-section 250 includes a shape such as a circle or other closed structure, Junction Regions 120A and 120B as well as Thin Reflectors 130A and 130B are optionally part of the same continuous structure. The position of Cross-sections 250 is shown as a dashed line in FIG. 2. Given these examples, other shapes will be apparent.

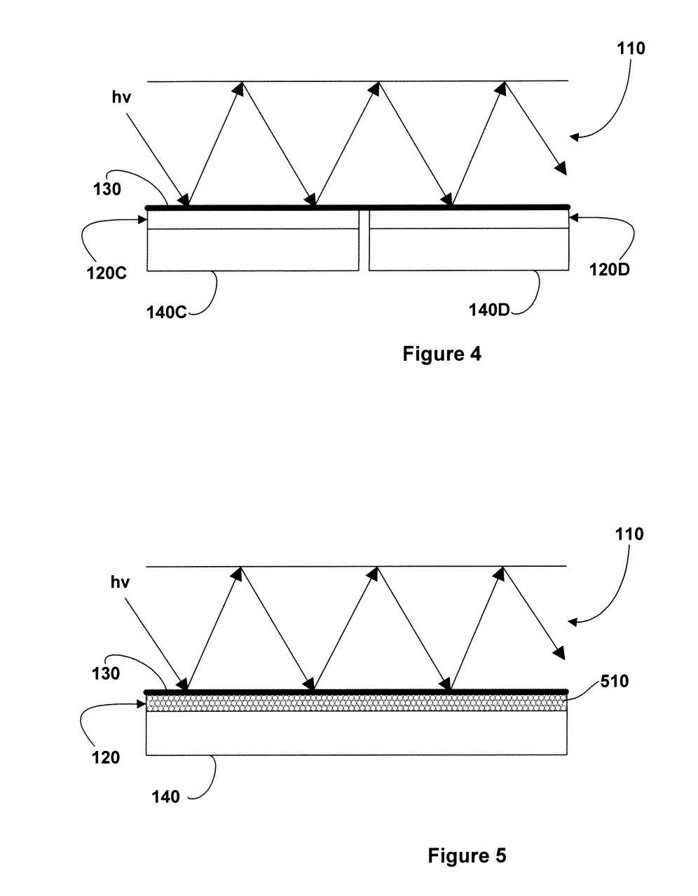

FIG. 4 illustrates a Reflection System 100 including regions that require different amounts of photon energy to generate a charge separation, according to various embodiments of the invention. These embodiments have the advantage that higher energy photons can be used to generate charge separation in materials having a greater work function, while lower energy photons are used to generate charge separation in materials having lower work functions. This results in an increase in the efficiency of generating useful work from light, such as sunlight, that includes photons over a range of energies. Different regions can be optimized to generate electrical energy from different ranges of photon energy.

As illustrated in FIG. 4, Junction Region 120 is separated into two or more parts, labeled 120C and 120D. These parts are each respectively configured to convert photons of different energy into charge separations. For example, in some embodiments, the part of Junction Region 120C that receives an electric field of reflecting light first is configured to absorb photons of higher energy relative to the part of Junction Region 120D that receives an electric field of the reflecting light second. In FIG. 4 this is shown as light entering Reflection Region 110 from the left and encountering Junction Region 120C before Junction Region 120D. Typically, a photon will have many opportunities to create a charge separation in Junction Region 120C before encountering Junction Region 120D. Thus, as light is reflected within Reflection Region 110 the light is progressively exposed to parts of Junction Region 120 configured to convert photons of lower and lower energy.

Each part of Junction Region 120C and 120D, in combination with the adjacent electrodes, represents what can be considered a separate photovoltaic cell. For the purposes of definition, the arrangement of cells illustrated in FIG. 4 is considered to be “serial.” This is in contrast with the “stacked” geometries in which photovoltaic cells are stacked one on top of the other, wherein light must pass all the way through one cell to reach another. In a serial photovoltaic cell arrangement, light need not pass all the way through a first cell in order to reach a second cell.

This configuration of Junction Region 120 may include the use of materials having different junction (e.g., band-gap or work function) energies. For example, the part of Junction Region 120 that is labeled 1200 may include a photoelectric requiring absorption of a 1.2 eV photon to produce charge separation, while the part of Junction Region 120 labeled 120D may include a photoelectric requiring absorption of a 1.4 eV photon to produce charge separation. Photoelectric materials having other work functions are included in various embodiments of the invention. Work functions are optionally chosen so as to maximize the useful energy extracted from photons. In some embodiments, the thickness of thin reflector 130 is selected in order to control wavelengths of light that are absorbed by each photovoltaic cell.

While FIG. 4 illustrates an example of Junction Region 120 that is separated into two parts, in alternative embodiments, Junction Region 120 is separated into three, four or more parts each having different work functions. Note that in order to reach a part of Junction Region 120 having a lower work function, a photon does not have to be transmitted all the way through a photoelectric material having higher work function. The photon merely needs to be reflected above such a material. Separated Junction Regions 120 may be placed on both sides of Reflection Region 110 in a manner similar to that illustrated in FIG. 1B.

Light is optionally exposed to those parts of Junction Region 120 that require the greatest amount of energy to produce a charge separation first. The light is then exposed to parts of Junction Region 120 that require a lower amount of photon energy to produce a charge separation. In this way, different wavelengths of the received light may be more efficiently converted to a voltage differential. Each part of Junction Region 120 is optionally coupled to an electrically separate part of Counter Electrode 140 on which a different voltage is produced as a result of the charge separation.

The material structure of Junction Region 120 is optionally configured to optimize the production of charge separations. For example, Junction Region 120 may include a layer of electron donating material followed by a layer of electron accepting material. (A third layer of intermediate electron affinity is optionally disposed between these layers.) These layers are optionally repeated alternatively. The type of layer closest to Thin Reflector 130 is typically selected to optimize current generation. For example, in one embodiment, the electron accepting region is closest to Thin Reflector 130 and an intermediate layer is disposed between the electron accepting region and the electron donating region. In some embodiments, this type of layering is possible because the direction (relative to Thin Reflector 130) of the electric field used to generate the charge separation is known. The structure, e.g., crystal structure, of Junction Region 120 is optionally configured to optimize the production and/or collection of charge separation based on this knowledge. The thicknesses of one or more layers are optionally selected based on how deep the electric field is expected to penetrate into the Junction Region 120 during reflection of a photon. For example, the thicknesses may be selected such that the electric field will reach just through the electron accepting and intermediate layers and approximately to the electron donating layer.

FIG. 5 illustrates a reflection system including Particles 510 disposed adjacent to a reflector, according to various embodiments of the invention. Particles 510 may be included at a density of less than a mono-layer, a mono-layer, or several layers. Particles 510 are optionally metallic and may vary in size from a few nanometers to one or more microns. The size and shape of Particles 510 are selected to couple electric fields to Junction Region 120.

As an alternative to or in addition to Particles 510 the interface between Thin Reflector 130 and Junction Region 120 optionally includes nanowires, nanotubes, nanometer sized groves, bumps, ridges, or other textures. The Particles 510 and/or textures are configured to act as waveguides for the incoming light in order to excite as many plasmons in the photoelectric as possible. The textures can be in the form of a grating configured to control plasmon frequency. In some embodiments the side of Thin Reflector 130 adjacent to Reflection Region is flat while the side of Thin Reflector 130 adjacent to Junction Region 120 is textured.

The Particles 510, other materials and/or textures are optionally in addition to the reflective/conductive material of Thin Reflector 130 and can be embedded in Thin Reflector 130 and/or Junction Region 120. The particles or wires are configured to excite plasmon resonance within the photoelectric layer and thereby distribute the incident electric field. The composition or dimensions of Particles 510, other materials and/or textures are optionally varied so as to control the wavelength range of light adsorbed. The Particles 510, other materials and/or textures include aluminum, silver, gold, copper, or other metal or non-metal species. Optionally an additional layer, e.g., a dielectric, is disposed between the particles or wires and Junction Region 120.

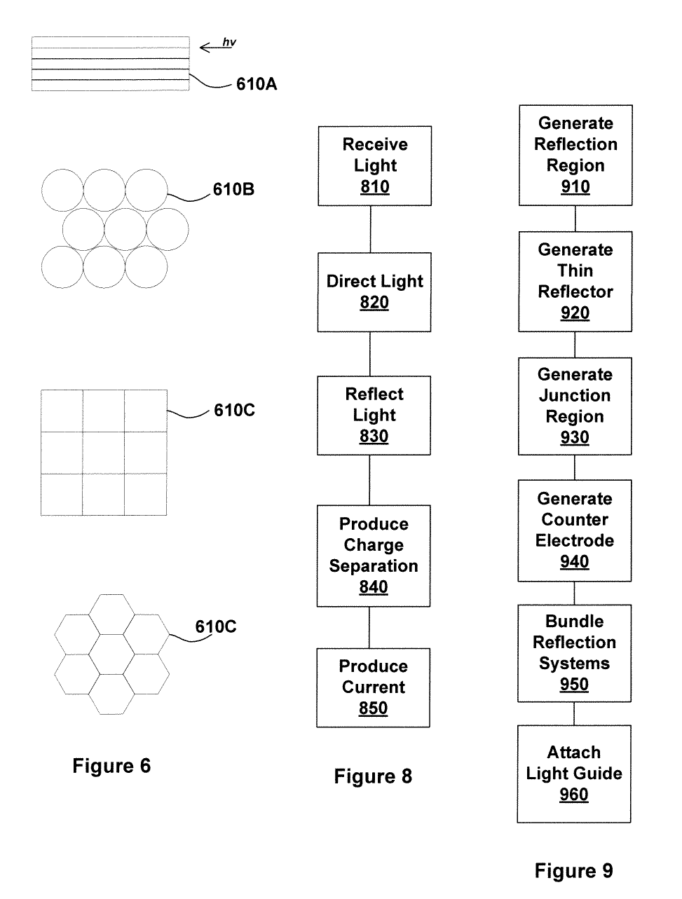

FIG. 6 illustrates ways in which reflection systems can be bundled, according to various embodiments of the invention. In a Stacking 610, parallel instances of Reflection System 100 are stacked together. In these instances different Reflection Systems 100 can share a common Counter Electrode 140 or have Counter Electrodes 140 that are in contact with each other. Light is directed in the plane of the figure into the narrow end of each of the Reflection Systems 100 as illustrated in FIG. 6.

In a Stacking 620, bundles of circular Reflection Systems 100 are packed together. These Reflection Systems 100 can include, for example, fiber optics. Light is directed into the Reflection Systems 100 perpendicular to the plane of the figure. In a Stacking 630, bundles of rectangular or square Reflection Systems 100 are packed together. Light is directed into these Reflection Systems 100 perpendicular to the plane of the figure. In a Stacking 640, bundles of hexagonal Reflection Systems 100 are stacked together and, again, light is directed into these from a direction perpendicular to the plane of the figure. Based on these examples, many other packing geometries will be obvious.

The bundled systems illustrated in FIG. 6 are optionally produced by first manufacturing each individual Reflection System 100 and then packing these individuals together. For example, the Stacking 620 can be achieved by first making a plurality fiber optics having Thin Reflector 130, Junction Region 120 and Counter Electrode 140, and then packing these fiber optics together. Optionally, Thin Reflector 130 and Counter Electrode 140 are disposed so that they do not reach opposing ends of the fiber optic so as to simplify electrical connections to Load 230.

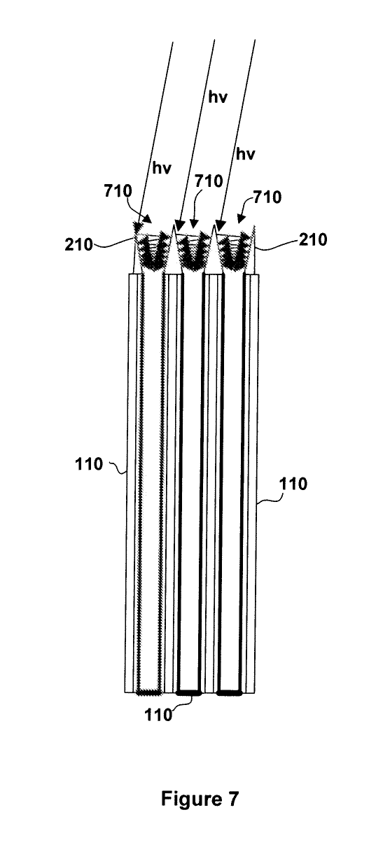

FIG. 7 illustrates an array of Reflection Systems 100 coupled to a Light Guide 210, according to various embodiments of the invention. In these embodiments, Light Guide 210 includes a plurality of Optical Elements 710 each configured to direct light to a different Reflection System 100. Optical Elements 710 can comprise reflective surfaces, lenses, channels, wave guides, and/or orifices. Optionally, Optical Elements 710 are configured to direct as much light as possible into Reflection Systems 100. Optical Elements 710 may be movable so as to follow the sun. The light received by Optical Elements 710 is optionally concentrated sunlight. In the examples illustrated by FIG. 7 the Optical Elements 710 may comprise an array of tapered holes in a reflective substrate. These holes have the same spacing as the underlying Reflection Systems 100.

FIG. 8 illustrates methods of generating an electronic current, according to various embodiments of the invention. The generated current is optionally used to drive Load 230. In a Receive Light Step 810, light is received by Reflection System 100. This light is typically sunlight and is optionally concentrated.

In a Direct Light Step 820, the received light is directed into Reflection Region 110. This direction optionally includes further concentrating of the light so as to increase the amount of light energy per unit area. In a Reflect Light Step 830, the directed light is reflected repeatedly from one or more Thin Reflector 130. Each of these reflections is away from an adjacent (nearest) Junction Region 120. At each reflection, the light produces an electric field that reaches Junction Region 120 through Thin Reflector 130. The electric field must penetrate Thin Reflector 130 to reach Junction Region 120. This occurs on the reflection of a photon. In various embodiments, the number of reflections that occur within Reflect Light Step 830 are greater than 10, 50, 100, 1000, 10,000, 100,000, or 1,000,000.

In a Produce Charge Separation Step 840, the penetrating electric field produced by a reflecting photon in Reflect Light Step 830 is used to produce a charge separation, e.g., a separation of positive and negative charges, within Junction Region 120. The charge separation occurs during a reflection and is caused by the penetrating part of the electric field through Thin Reflector 130. Photons that are not absorbed by the generation of a charge separation are typically reflected back into Reflection Region 110 and, thus, are reflected again in a repeat of Reflect Light Step 830 and have further opportunities to produce charge separation. In some embodiments, a greater fraction of the total received light energy is used to produce charge separation, relative to a fraction of the total received light energy that is thermally absorbed.

In a Produce Current Step 850, the separated charges are received at Thin Reflector 130 and Counter Electrode 140, respectively. This produces a voltage difference between these conductors, and a resulting current through Load 230. This current is optionally used to perform useful work.

FIG. 9 illustrates methods of making a Reflection System 100, according to various embodiments of the invention. These methods include making the various layers discussed herein and optionally bundling several Reflection Systems 100 together. The layers may be made using various gas phase, vacuum or liquid based manufacturing techniques known in the art.

In a Generate Reflection Region Step 910, Reflection Region 110 is produced. This may be accomplished by, for example, drawing a fiber optic; forming a glass or crystalline, poly-crystalline, micro-crystalline, or glass plate; and/or extruding, depositing, machining, or otherwise generating a bulk transparent material. In some embodiments, Generate Reflection Region Step 910 includes producing one or more orifice in a bulk material.

In a Generate Thin Reflector Step 920, Thin Reflector 130 is produced. In various embodiments, Generate Thin Reflector Step 920 includes depositing a metallic layer using electrochemical, liquid, gas phase or vacuum deposition techniques. The thickness of this layer is selected to achieve the desired reflectivity and electric field penetration properties. The resulting Thin Reflector 130 optionally includes structures, particles, crystals, and/or the like that are configured to increase the coupling of a penetrating electric field into Junction Region 120. The composition and/or characteristics of Thin Reflector 130 are optionally varied as a function of location so as to select which wavelengths of light preferentially penetrate to Junction Region 120.

In a Generate Junction Region Step 930, Junction Region 120 is produced. Typically, Generate Junction Region Step 930 includes several sub-steps in which “n,” “i” and/or “p” layers are produced. These layers can be produced using any of the semiconductor or photovoltaic techniques know in the art. Junction Region 120 is produced in electrical contact with Thin Reflector 130 as illustrated elsewhere herein. Generate Junction Region Step 930 optionally includes producing two, three, four or more parts of Junction Region 120 that have different work functions. In some embodiments Generate Thin Reflector Step 920 is achieved merely by selecting the composition of Reflection Region 110 and Junction Region 120 such that a significant change in refraction index occurs at their boundary.

In a Generate Counter Electrode Step 940, Counter Electrode 140 is produced. In various embodiments, Generate Counter Electrode Step 940 includes depositing a metallic layer using electrochemical, liquid, gas phase or vacuum deposition techniques. Alternatively, Counter Electrode 140 can be produced from a bulk material by etching, machining, extruding, molding, cutting etc. Counter Electrode 140 is produced in electrical contact with Junction Region 120 as illustrated elsewhere herein.

Steps 920-940 can be performed in various orders. For example, Step 940 may be performed first and then Step 930 is used to produce Junction Region 120 using Counter Electrode 140 as a substrate, then Thin Reflector 130 is produced using Junction Region 120 as a substrate. When Reflection System 100 is made in this manner Generate Reflection Region Step 910 is optional and Reflection Region 110 may comprise, for example, merely an air gap bounded by one or more Thin Reflector 130.

In an Optional Bundle Reflection Systems 950 two or more Reflection Systems 100 are bundled together as illustrated, for example, in FIGS. 6 and 7. This bundling optionally includes making electrical contact between various Counter Electrode 140.

In an optional Attach Light Guide Step 960 one or more Reflection Systems 100 are couple to a Light Guide 210. In one embodiment, the Light Guide 210 includes an array of optics (e.g., lenses, channels, and/or orifices), configured to direct light into a plurality of Reflection Systems 100.

Several embodiments are specifically illustrated and/or described herein. However, it will be appreciated that modifications and variations are covered by the above teachings and within the scope of the appended claims without departing from the spirit and intended scope thereof. For example the thicknesses and/or relative dimensions of the various elements illustrated in the figures are NOT necessarily to scale. Likewise, the length to thickness ratios of the various elements illustrated in the figures may vary substantially from the illustrations. Further, for clarity the number of reflections shown in the drawings are optionally much fewer and/or at a less perpendicular angle than can occur in practice. The method steps disclosed herein are optionally performed in alternative orders.

The embodiments discussed herein are illustrative of the present invention. As these embodiments of the present invention are described with reference to illustrations, various modifications or adaptations of the methods and or specific structures described may become apparent to those skilled in the art. All such modifications, adaptations, or variations that rely upon the teachings of the present invention, and through which these teachings have advanced the art, are considered to be within the spirit and scope of the present invention. Hence, these descriptions and drawings should not be considered in a limiting sense, as it is understood that the present invention is in no way limited to only the embodiments illustrated.

What is claimed is:

1. A system comprising:
a first electrode;
a junction region including photovoltaic material, and in electrical contact with the first electrode; and
a second electrode in electrical contact with the junction region, configured to reflect at least 20% of incident light, and disposed such that energy of a photon must pass through the second electrode in order to reach the junction region, wherein the photovoltaic material is configured to produce a charge separation from the photon energy passed through the second electrode.

2. The system of claim 1, wherein the junction region comprises a first part configured to absorb the photon within a first energy range and a second part configured to absorb the photon within a second different energy range.

3. The system of claim 2, wherein the first and second parts of the junction region are configured such that an electric field of the photon will penetrate but not pass through the first part before penetrating the second part.

4. The system of claim 3, wherein the first and second parts of the junction region are disposed such that an electric field of the photon penetrates the first part first and thereafter the second part, the first part requiring a higher energy photon to generate the charge separation relative to the second part.

5. The system of claim 2, wherein the junction region further comprises at least a third part configured to adsorb the photon within a third energy range and a fourth part configured to adsorb the photon within a fourth energy range, the first, second, third and fourth energy ranges each being different from each other.

6. The system of claim 2, wherein the first and second parts of the junction region are both in contact with the second electrode and disposed to receive the energy of the photon through the second electrode.

7. The system of claim 1, wherein the second electrode is disposed such that the photon is reflected from the second electrode at least 1000 times.

8. The system of claim 1, wherein the junction region includes more than two photovoltaic cells in a serial configuration.

9. The system of claim 1, wherein the second electrode is configured to reflect at least 90% of the incident light.

10. The system of claim 1, wherein the second electrode is configured to reflect the incident light away from the photovoltaic material.

11. A system comprising:
a reflection region configured for light to be repeatedly reflected from a first reflector, the first reflector being conductive and having a thickness configured for an electric field of the reflected light to penetrate through the first reflector;
a first junction region comprising a photovoltaic material configured to absorb a photon from the penetrating electric field so as to produce a separation of charges; and
a first counter electrode configured to receive one of the separated charges, resulting in a voltage differential between the first reflector and the first counter electrode.

12. The system of claim 11, further comprising a terminal reflector configured to reflect light back through the reflection region.

13. The system of claim 11, wherein the reflection region is tapered to a point.

14. The system of claim 11, further comprising a light guide configured to direct the light into the reflection region.

15. The system of claim 11, wherein the reflection region is characterized by a polygon cross-section.

16. The system of claim 11, wherein the reflection region is characterized by an oval or circular cross-section.

17. The system of claim 11, further comprising a second junction region and a second counter electrode, the second junction region being configured to absorb the photon from an electric field penetrating a second reflector, and the second counter electrode being configured to receive a charge resulting from this photon absorption.

18. An electric power generation system comprising:
a plurality of photoelectric devices each comprising
a first electrode including a first reflector,
a second electrode configured to reflect at least 20% of incident light, and
a junction region disposed between the first electrode and the second electrode and configured to produce a charge separation from photon energy received through the second electrode; and
a load configured to receive a current resulting from the charge separation produced at each of the plurality of the photoelectric devices.

19. The electric power generation system of claim 18, wherein the load includes a DC to AC converter.

20. A method of converting light to an electric current, the method comprising:
receiving the light;
directing the received light into a reflection region comprising reflective surfaces;
reflecting the light from the reflective surfaces;
using an electric field to produce a charge separation within a junction region, the electric field resulting from the light and penetrating through one of the reflective surfaces during a reflection; and
using the charge separation to produce the electric current.

21. The method of claim 20, further comprising giving the light multiple opportunities to produce the charge separation.

22. The method of claim 20, further comprising giving the light an opportunity to produce the charge separation at each of the reflective surfaces.

23. The method of claim 20, wherein the light is reflected from the reflective surfaces more than 1000 times before producing the charge separation.

24. The method of claim 20, wherein the step of using an electric field to produce the charge separation includes first exposing a photon to a first part of the junction region having a first work function and thereafter exposing the photon to a second part of the junction having a second lower work function.

25. The method of claim 20, wherein the reflective surfaces are configured to reflect at least 50% of the light.

26. A method of producing a photovoltaic, the method comprising:
generating a thin reflector configured for an electric field to penetrate upon reflection of a photon, the thin reflector being configured to conduct a charge and to reflect at least 20% of incident photons;
generating a junction region in contact with the thin reflector and configured to produce a charge separation from the penetrating electric field;
generating a counter electrode in contact with the junction region, the junction region being disposed between the counter electrode and the thin reflector such that an electric field must penetrate the thin reflector to produce the charge separation; and
generating a reflection region configured such that a photo reflects from the thin reflector multiple times.

27. The method of claim 26, wherein the reflection region includes an air gap.

28. The method of claim 26, wherein the reflection region includes a fiber optic.

29. The method of claim 26, wherein the reflection region includes a glass, crystal, or micro-crystalline structure.

30. The method of claim 26, wherein the junction region includes more than three photovoltaic cells in a serial arrangement.
